(19) United States
(12) Patent Application Publication
(10) Pub. No.: US 2018/0258531 A1
(43) Pub. Date: Sep. 13, 2018

(54) DIFFUSER DESIGN FOR FLOWABLE CVD

(71) Applicant: Applied Materials, Inc., Santa Clara, CA (US)

(72) Inventors: Ying MA, Castro Valley, CA (US); Daemian RAJ, Fremont, CA (US); Greg CHICHKANOFF, Mountain View, CA (US)

(21) Appl. No.: 15/893,184

(22) Filed: Feb. 9, 2018

Related U.S. Application Data
(60) Provisional application No. 62/469,267, filed on Mar. 9, 2017.

(51) Int. Cl. C23C 16/455; H01J 37/32; C23C 16/513

(52) U.S. Cl. CPC C23C 16/45565; H01J 37/32449; H01J 2237/3321; C23C 16/513; H01J 37/32862; H01J 37/32357

(57) ABSTRACT

Implementations described herein generally relate to an apparatus for forming flowable films. In one implementation, the apparatus is a diffuser including a body having a first surface and a second surface opposing the first surface, a plurality of dome structures formed in the first surface, a central manifold formed in the second surface, and a plurality of tubular conduits coupled between the central manifold and a respective one of the plurality of dome structures, at least a portion of the plurality of tubular conduits being positioned diagonally relative to a plane of the first surface.

### CROSS-REFERENCE TO RELATED APPLICATION

This application claims priority from U.S. Provisional Patent Application Ser. No. 62/469,267, filed Mar. 9, 2017, which is hereby incorporated by reference herein.

### BACKGROUND

### Field

Implementations described herein generally relate to methods and apparatus for forming flowable films using a plasma of precursor gases, in particular to a diffuser design for flowing a plasma of precursor gases utilized in electronic device manufacture.

### Description of the Related Art

Semiconductor device geometries have dramatically decreased in size since their introduction several decades ago. Modern semiconductor fabrication equipment routinely produce devices with 45 nm, 32 nm, and 28 nm feature sizes, and new equipment is being developed and implemented to make devices with even smaller geometries. The decreasing feature sizes result in structural features on the device having decreased width. The widths of gaps and trenches on the devices are narrow such that filling the gap with dielectric material becomes more challenging. Recently, flowable films have been used to fill the gaps, such as high-aspect ratio gaps. To achieve flowability, films have been deposited into the gaps using chemical vapor deposition (CVD) with radicals generated in a remote plasma source (RPS) and delivered to a surface of a substrate using a diffuser. Plasma uniformity is important in order to form a uniform film on a substrate. For example, film thickness/density across the entire surface area of the substrate is desired. However, conventional diffusers typically include different conductance paths for the plasma. The different conductance paths may cause a portion of the plasma to recombine, which may produce non-uniformity in the plasma. This may results in defects, deposition rate drift, or other anomalies on the surface of the substrate.

Therefore, an improved method and apparatus is needed to form uniform films on a substrate.

### SUMMARY

Implementations described herein generally relate to apparatus and methods for forming flowable films. In one implementation, the apparatus is a diffuser including a body having a first surface and a second surface opposing the first surface, a plurality of dome structures formed in the first surface, a central manifold formed in the second surface, and a plurality of tubular conduits coupled between the central manifold and a respective one of the plurality of dome structures, at least a portion of the plurality of tubular conduits being positioned diagonally relative to a plane of the first surface.

In some embodiments, each of the tubular conduits is composed of small diameter channels coupled to large diameter channels. The length of the small conduits is substantially the same while the lengths of the large conduits are different. The small diameter conduits with same length are utilized to maintain the same conductance between other small diameter conduits. The large conduits may be utilized to compensate for the varying distance differences between the central manifold and the edge of the diffuser. In another implementation, a processing chamber includes a diffuser, a chamber wall, wherein the diffuser is disposed over the chamber wall, a substrate support disposed below the diffuser, and a plasma delivery ring disposed between the diffuser and the substrate support.

In another implementation, the apparatus includes a body having a first surface and a second surface opposing the first surface, a plurality of dome structures formed in the first surface, each dome structure having an opening, a central manifold formed in the second surface, the central manifold having a plurality of openings, and a plurality of tubular conduits each coupled between one opening in the central manifold and a respective opening in one of the plurality of dome structures, wherein each of the plurality of tubular conduits include a first portion and a second portion that is different than the first portion and at least a portion of the plurality of tubular conduits are positioned diagonally relative to a plane of the first surface, and wherein the number of dome structures is equal to the number of tubular conduits.

In another implementation, a processing chamber includes a diffuser, a first remote plasma source disposed over the diffuser, a chamber wall, wherein the diffuser is disposed over the chamber wall, a second remote plasma source coupled to the chamber wall, a substrate support disposed below the diffuser, and a plasma delivery ring disposed between the diffuser and the substrate support.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only selected implementations of this disclosure and are therefore not to be considered limiting of its scope, for the disclosure may admit to other equally effective implementations.

FIG. 1 is a schematic top plan view of a processing tool according to one implementation.

FIG. 2A is a schematic cross-sectional side view of a processing chamber according to one implementation.

FIG. 2B is an enlarged sectional view of the diffuser of FIG. 2A.

FIG. 3A is an isometric top view of a diffuser according to another implementation.

FIG. 3B is an isometric bottom view of the diffuser of FIG. 3A.

FIG. 4 is an isometric cross-sectional view of a diffuser wherein a portion of the body is removed in order to show the tubular conduits and the central manifold in greater detail.

To facilitate understanding, identical reference numerals have been used, wherever possible, to designate identical elements that are common to the Figures. Additionally, elements of one implementation may be advantageously adapted for utilization in other implementations described herein.

### DETAILED DESCRIPTION

Implementations described herein generally relate to methods and apparatus for forming flowable films using a diffuser. In one implementation, the apparatus is a processing chamber including a first remote plasma source (RPS) coupled to a lid of the processing chamber which includes a diffuser. The processing chamber may include a second RPS coupled to a side wall of the processing chamber. The first RPS is utilized for delivering deposition radicals into a processing region in the processing chamber through the diffuser. The second RPS is utilized for delivering cleaning radicals into the processing region. Having separate RPS's for deposition and clean along with introducing radicals from the RPS's into the processing region using separate delivery channels minimize cross contamination and cyclic change on the RPS's, leading to improved deposition rate drifting and particle performance.

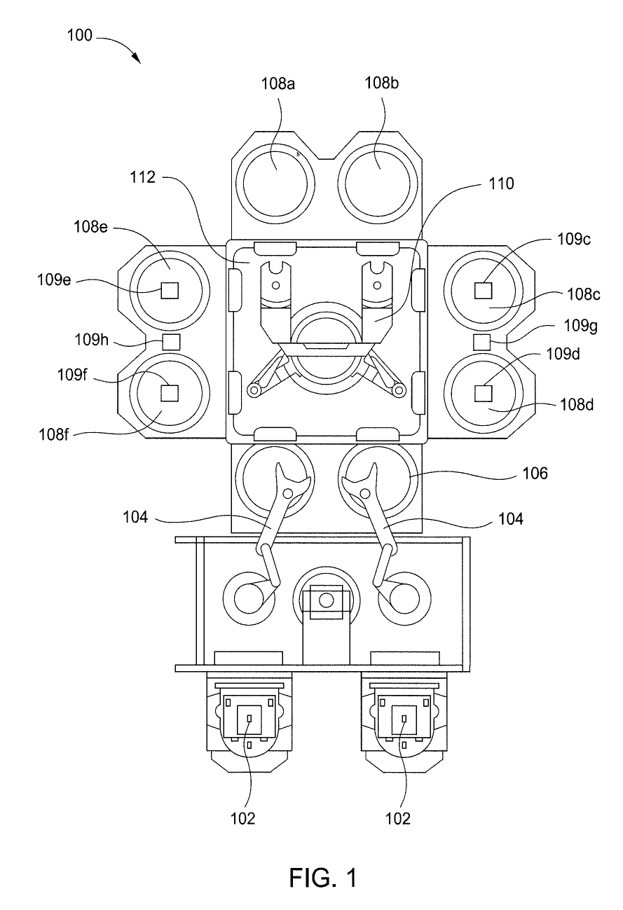

FIG. 1 is a schematic top plan view of a processing tool 100 according to one implementation. The processing tool 100, such as a cluster tool as shown in FIG. 1, includes a pair of front opening unified pods (FOUPs) 102 for supplying substrates, such as semiconductor wafers, that are received by robotic arms 104 and placed into load lock chambers 106. A second robotic arm 110 is disposed in a transfer chamber 112 coupled to the load lock chambers 106. The second robotic arm 110 is used to transport the substrates from the load lock chamber 106 to processing chambers 108a-108f coupled to the transfer chamber 112.

The processing chambers 108a-108f may include one or more system components for depositing, annealing, curing and/or etching a flowable film on the substrate. In one configuration, two pairs of the processing chambers (e.g., 108c-108d and 108e-108f) may be used to deposit the flowable film on the substrate, and the third pair of the processing chambers (e.g., 108a-108b) may be used to anneal/cure the deposited flowable film. In another configuration, the same two pairs of processing chambers (e.g., 108c-108d and 108e-108f) may be used to both deposit and anneal/cure the flowable film on the substrate, while the third pair of the processing chambers (e.g., 108a-108b) may be used to cure the flowable film on the substrate with ultraviolet (UV) or electron-beam (E-beam). The processing chambers used for depositing the flowable film on the substrate (e.g., 108c, 108d, 108e, 108f) may each include a first RPS (e.g., 109c, 109d, 109e, 109f) disposed on a lid of the processing chamber.

Each pair of processing chambers used for depositing the flowable film on the substrate (e.g., 108c-108d and 108e-108f) share a second RPS (e.g., 109g, 109h), which is disposed in between each pair of processing chambers. For example, the second RPS 109g is disposed between the processing chamber 108c and the processing chamber 108d, and the second RPS 109h is disposed between the processing chamber 108e and processing chamber 108f. In some implementations, each pair of processing chambers 108a-108b, 108c-108d, and 108e-108f is a single processing chamber including two substrate supports and capable of processing two substrates. In such implementations, each processing chamber includes two first RPS's, each disposed on the lid of the processing chamber over a corresponding substrate support, and one second RPS disposed on the lid of the processing chamber between the two first RPS's.

Each of the first RPS's 109c, 109d, 109e, and 109f is configured to excite a precursor gas, such as a silicon containing gas, an oxygen containing gas, and/or a nitrogen containing gas, to form precursor radicals that form a flowable film on the substrate disposed in each of the processing chambers 108c, 108d, 108e, and 108f, respectively. Each of the second RPS's 109g and 109h is configured to excite a cleaning gas, such as a fluorine containing gas, to form cleaning radicals that clean components of each pair of the processing chambers 108c-108d and 108e-108f, respectively.

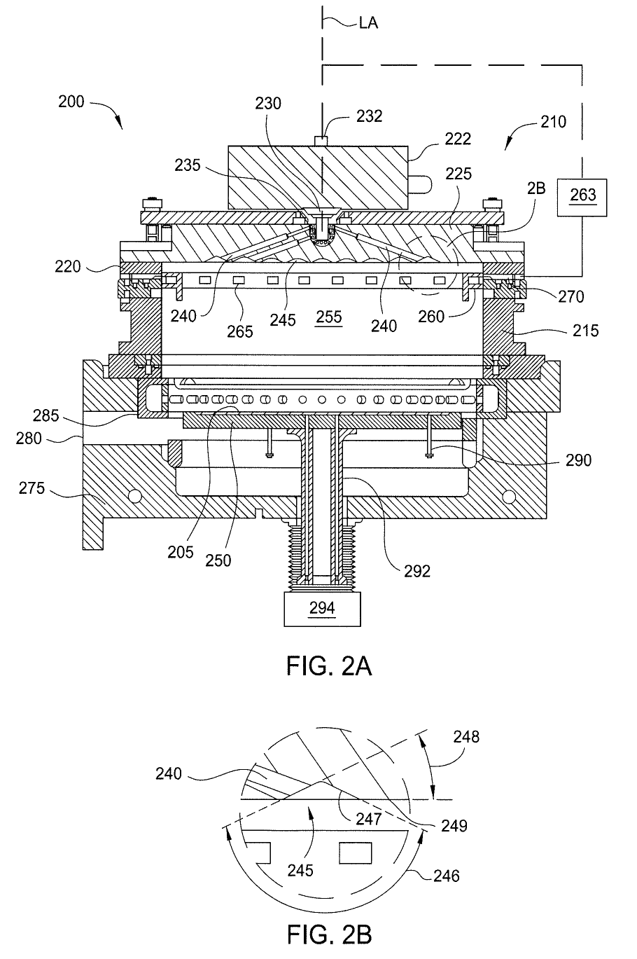

FIG. 2A is a schematic cross-sectional side view of a processing chamber 200 according to one implementation. The processing chamber 200 may be a deposition chamber, such as a CVD deposition chamber. The processing chamber 200 may be any of the processing chambers 108a-108f shown in FIG. 1. The processing chamber 200 may be configured to deposit a flowable film on a substrate 205. The processing chamber 200 includes a lid assembly 210 disposed over a chamber wall 215. An insulating ring 220 may be disposed between the lid assembly 210 and the chamber wall 215.

A first RPS 222 is disposed on the lid assembly 210 where ions and/or radicals (e.g., plasma) of a precursor gas are formed. The plasma formed in the first RPS 222 are flowed into a diffuser 225 of the processing chamber 200 via a plasma inlet assembly 230. A precursor gas inlet 232 is provided on the first RPS 222 for flowing one or more precursor gases into the first RPS 222. The diffuser 225 may be a showerhead that evenly distributes plasma from the first RPS 222 onto the substrate 205.

The diffuser 225 includes a central manifold 235 that is in fluid communication with the plasma inlet assembly 230. The central manifold 235 includes a plurality of ports that are coupled to tubular conduits 240. Each of the tubular conduits 240 may be a drilled hole formed in a body of the diffuser 225. Each of the tubular conduits 240 terminate in a respective dome structure 245 on a surface of the diffuser 225 facing the substrate 205.

FIG. 2B is an enlarged sectional view of FIG. 2A showing details of the diffuser 225. Each of the dome structures 245 include a wall 247 that may be angled or include a radius. In one embodiment, the wall 247 of at least a portion of the dome structures 245 are formed at an angle 248 relative to a first (bottom) surface 249 of the diffuser 225. The angle 248 may be less than about 20 degrees, such as 16 degrees to 20 degrees, for example about 18 degrees. In some embodiments, the dome structures 245 are configured as a flared opening having a flare angle 246 of about 115 degrees to about 130 degrees, such as about 120 degrees. Construction and performance of the diffuser 225 is described in more detail below.

The processing chamber 200 includes a substrate support 250 for supporting the substrate 205 during processing. A processing region 255 is defined between a lower surface of the diffuser 225 and an upper surface of the substrate support 250. A plasma delivery ring 260 is disposed between the diffuser 225 and the substrate support 250. The plasma delivery ring 260 is utilized to deliver cleaning radicals into the processing region 255 from a second RPS 263 coupled to the chamber wall 215 of the processing chamber 200. The plasma delivery ring 260 includes a plurality of channels 265 for delivering ions and/or radicals (i.e., plasma) of a cleaning gas into the processing region 255. The second RPS 263 may be coupled to an inlet 270 formed in the chamber wall 215, and the plasma delivery ring 260 is aligned with the inlet 270 to receive the cleaning plasma from the second RPS 263. Since the plasma from the diffuser 225 mixes and reacts in the processing region 255 below the diffuser 225, deposition primarily occurs below the diffuser 225 (except for some minor back diffusion). Thus, the components of the processing chamber 200 disposed below the diffuser 225 should be cleaned after periodic processing.

In an alternative or additional embodiment, the second RPS 263 may be coupled to the plasma inlet assembly 230 such that plasma of a cleaning gas may be provided to flow to the processing region 255 through the diffuser 225. Thus, interior surfaces of the diffuser 225 may be cleaned, as well as components below the diffuser 225, if desired.

Cleaning is referring to removing material deposited on surfaces of the chamber components. Since minor deposition may occur at locations above (upstream) of the diffuser 225, flowing cleaning plasma into the diffuser 225 can lead to component surface changes, such as surface fluorination, since fluorine radicals may be used as cleaning radicals. Thus, introducing cleaning radicals from the first RPS 222 may lead to unnecessary cleaning of components above the diffuser 225. Therefore, in some embodiments, the cleaning radicals are introduced into the processing region 255 at a location below (downstream of) the diffuser 225.

Embodiments of the diffuser 225 provide a low surface-to-volume ratio and a low volume at the same time. Low volume minimizes the plasma residence time in the diffuser 225 while a low surface-to-volume ratio provides less surface interactions for radical recombination. Therefore, plasma paths (i.e., volumes of the tubular conduits 240) may minimize recombination of the both deposition and clean plasmas. In one example, if clean plasma flow in the volumes of the tubular conduits 240, surface morphology changes, which may be due to fluorine recombination, can be minimized.

The embodiment of the diffuser 225 also results in uniform plasma, or substantially uniform plasma, both for deposition and clean plasmas, flowing through the diffuser 225. Substantially may be defined as about 90% to slightly less than about 100% plasma uniformity (e.g., 10% non-uniformity). if a cleaning plasma flow through the diffuser 225, a substantially uniform plasma may further benefits on minimizing the cleaning time, as well as minimize local over-clean and particle generation.

In some embodiments, the first RPS 222 is configured to excite a precursor gas, such as a silicon containing gas, an oxygen containing gas, and/or a nitrogen containing gas, to form a plasma that provides a flowable film on the substrate 205 disposed on the substrate support 250. The second RPS 263 is configured to excite a cleaning gas, such as a fluorine containing gas, to form a cleaning plasma that cleans components of the processing chamber 200, such as the substrate support 250 and the chamber wall 215. Having the first RPS 222 disposed on the lid assembly 210 of the processing chamber 200 while the second RPS 263 coupled to the chamber wall 215 can achieve better deposition uniformity due to priority on deposition. In addition, introducing the cleaning plasma between the diffuser 225 and the substrate support 250 can achieve high clean etch rate and improve clean rate distribution. Furthermore, the plasma used for depositing the flowable film on the substrate 205 are introduced into the processing region by the diffuser 225, while the radicals used for cleaning the components of the processing chamber 200 are introduced into the processing region 255 by the plasma delivery ring 260. By separating the channels used for delivering deposition plasma and cleaning plasma, cross contamination and cyclic change on the components of the processing chamber 200 are reduced, which results in improved deposition rate drifting and particle performance.

The processing chamber 200 further includes a bottom 275, a slit valve opening 280 formed in the bottom 280, and a pumping ring 285 coupled to the bottom 280. The pumping ring 285 is utilized to remove residual precursor gases and plasma from the processing chamber 200. The processing chamber 200 further includes a plurality of lift pins 290 for raising the substrate 205 from the substrate support 250 and a shaft 292 supporting the substrate support 250. The shaft 292 is coupled to a motor 294 which can rotate the shaft 292, which in turn rotates the substrate support 250 and the substrate 205 disposed on the substrate support 250. Rotating the substrate support 250 during processing or cleaning can achieve improved deposition uniformity as well as clean uniformity.

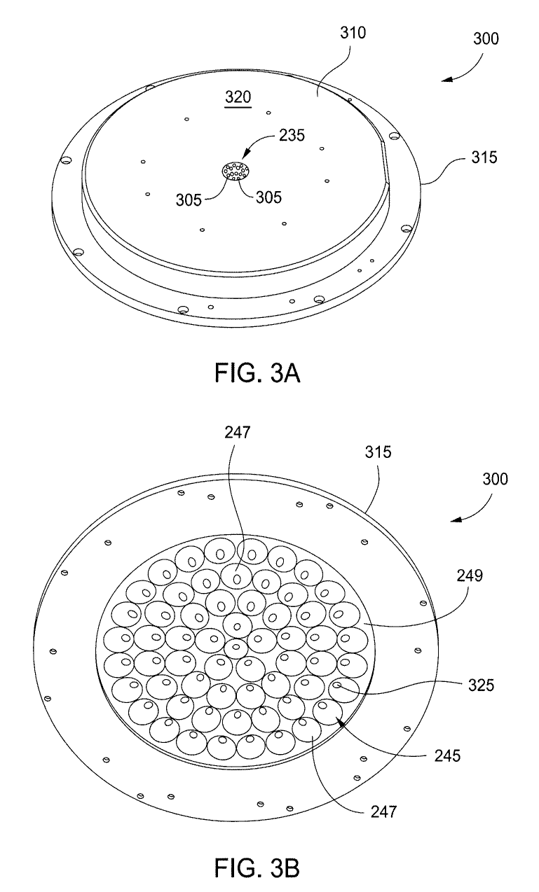

FIG. 3A is an isometric top view of a diffuser 300 and FIG. 3B is an isometric bottom view of the diffuser 300 of FIG. 3A. The diffuser 300 may be utilized in the processing chamber 200 as the diffuser 225 as described in FIG. 2A.

The diffuser 300 includes the plasma inlet assembly 230 as described in FIG. 2A. The plasma inlet assembly 230 includes a plurality of openings 305 that couple to the tubular conduits 240 (shown in FIG. 2A). The diffuser 300 also includes a body 310 having a mounting flange 315 coupled thereto. The body 310 and the mounting flange 315 may be fabricated from a single material, such as aluminum. The central manifold 235 may comprise a perforated cup. The central manifold 235 may be milled or drilled into a second (top) surface 320 of the body 310. The top surface 320 may be substantially parallel to the first surface 249 (shown in FIG. 2B and 3B). As shown in FIG. 3B, the wall 247 of at least a portion of the dome structures 245 may touch a wall 247 of an adjacent dome structure 245. Each of the tubular conduits 240 (shown in FIG. 2) terminate in an offset opening 325 formed in a corresponding wall 247 of the dome structures 245.

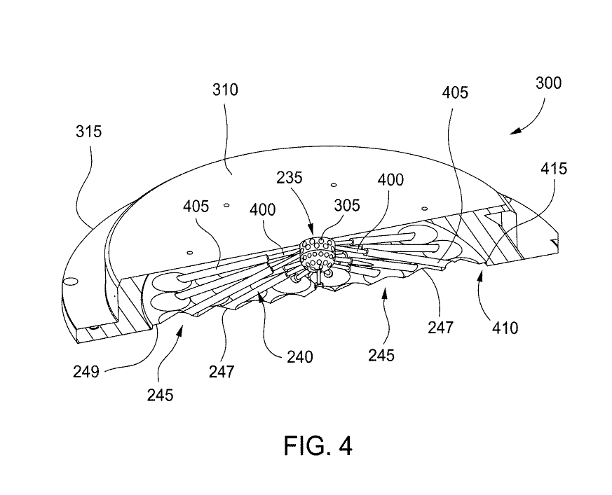

FIG. 4 is an isometric cross-sectional view of the diffuser 300 wherein a portion of the material of the body 310 is removed in order to show a portion of locations of the surfaces of the tubular conduits 240 and the central manifold 235 in greater detail.

A single tubular conduit 240 is positioned between the central manifold 235 and a respective dome structure 245. Each of the tubular conduits 240 may include a first portion 400 coupled to a second portion 405. Each of the first portions 400 may have a diameter that is less than a diameter of each of the respective second portions 405 coupled thereto. Each first portion 400 of the tubular conduits 240 couples to a single opening 305 of the central manifold 235. The openings 305 of the central manifold 235 serve as an entry point of plasma into the first portion 400 of the tubular conduits 240. A diameter of the openings 305 and the diameter of the first portion 400 of the tubular conduits 240 provide a high flow resistance and/or a high pressure gradient. The lengths of each of the first portions 400 may be substantially the same or varied to a desired ratio. In some embodiments, the length of the first portions 400 may be substantially the same in order to control conductance of the plasma flowing therein. Therefore, the first portion 400 of the tubular conduits 240 may also control uniform or desired flow distribution of the plasma from the central manifold 235.

Each second portion 405 of the tubular conduits 240 may have a length that is greater than a length of the respective first portion 400 of the tubular conduits 240. As discussed above, the second portion 405 of the tubular conduits 240 include a diameter (e.g., mean inside diameter) that is greater than a diameter (e.g., mean inside diameter) of the first portion 400 of the tubular conduits 240. The second portion 405 may have a flow resistance that is less than a flow resistance of the first portion 400 of the tubular conduits 240. The first portion 400 and the second portion 405 of the tubular conduits 240 may be machined (e.g., drilled) from a respective dome structure 245 The enlarged inside diameter of the second portion 405 facilitates ease in drilling of the respective first portion 400 and opening 305. The dome structures 245 facilitate diffusion of plasma in local areas of a substrate (shown in FIG. 2) and may be a transient flow channel between the offset openings 325 (shown in FIG. 3B) of the tubular conduits 240 and an annular recessed area 410 (the first surface 249 of the diffuser 225). The annular recessed area 410 may be formed by a step 415 formed in the body 310 inwardly of the mounting flange 315. The annular recessed area 410 may facilitate mixing of plasma from the individual tubular conduits 240. The annular recessed area 410 may also minimize a pattern of local non-uniformity due to the volumes provided by the dome structures 245.

The number of dome structures 245 equal the number of tubular conduits 240. In some embodiments, the number of dome structures 245 are greater than about 30. A diameter of the dome structures 245 (based on the edges of walls 247 measured at the first surface 249 of the diffuser 225 may be about 1.5 inches to about 2 inches. In some embodiments, a diameter of the first portion 400 of the tubular conduits 240 is about 0.12 inches to about 0.2 inches, such as about 0.15 inches. In other embodiments, a diameter of the second portion 405 of the tubular conduits 240 is about 0.22 inches to about 0.32 inches, such as about 0.28 inches. Lengths of the tubular conduits 240 may vary between about 1.5 inches to about 7 inches. Angles of the tubular conduits 240 relative to a longitudinal axis LA of the diffuser 225 (shown in FIG. 2A) may vary depending on locations thereof. For example, an outer (e.g., longer) tubular conduit 240 may be formed at about 20 degrees relative to the longitudinal axis LA of the diffuser 225 while the center tubular conduit 240 may be angled at about 0 degrees relative to the longitudinal axis LA of the diffuser 225 (e.g., parallel to the longitudinal axis LA).

Embodiments of the diffuser 225 and/or the diffuser 300 as described herein minimize plasma non-uniformity as compared to conventional showerheads. For example, a conventional showerhead may have a first plate having multiple perforations, a second plate opposing the first plate having a central inlet formed therein, and a plenum formed between the first and second plate. Plasma flows though the central inlet and a portion of that plasma flows through the multiple perforations in the first plate. However, due to this construction of the conventional showerhead, the plasma density is not distributed uniformly to a substrate for multiple reasons. Flow paths of the plasma is different (e.g., longer for perforations spaced away from the central inlet as opposed to the perforations directly below the central inlet). The longer flow paths may facilitate recombination of some of the plasma and therefore provides a plasma to a substrate with a high non-uniformity percentage. In addition, collisions with surfaces of the first plate, the second plate and/or the walls of the plenum may cause the plasma to lose energy and recombine. Variations of the conventional showerhead described have been attempted. For example, larger perforations at the edge of the second plate as opposed to perforations in a central portion of the second plate, multiple plasma inlets formed in the first plate, as well as coatings of the walls of the plenum and/or the first and second plate have been attempted. However, plasma density at the substrate surface has a high percentage of non-uniformity with these conventional showerhead designs. These conventional showerheads also allow recirculation of plasma, which may cause plasma loss due to recombination.

Another conventional plasma distribution design includes a plate with an expanding tapered surface extending from a central inlet toward a periphery of a substrate. A baffle may be positioned adjacent to the central inlet to direct plasma toward a periphery of the substrate. This conventional design may minimize plasma losses by minimizing the effective surface area as compared to the conventional showerhead as described above. However, this conventional design affords little control on the plasma flow pattern and allows recirculation of plasma, which may cause plasma loss due to recombination. This conventional design is also flow rate dependent. For example, when the flow rate is high, the plasma impacts the baffle at a higher speed, and an angle of deviation is smaller than an angle of deviation at a lower flow rate. Additionally, the baffle may have a temperature much higher than a temperature of the expanding tapered surface. This may cause many problems such as reactions with plasma in proximity to the baffle as well as failure of the baffle (e.g., melting of the baffle).

Embodiments of the diffuser 225 and/or the diffuser 300 as described herein has a much lower effective surface area than the conventional showerhead designs described above. This reduces recombination of plasma by minimizing surface collisions. Additionally, the fluid volume of the diffuser 225 and/or the diffuser 300 as described herein is less than conventional showerhead designs which reduces residence time of the plasma therein as well as reducing recombination due to surface collisions. Embodiments of the diffuser 225 and/or the diffuser 300 as described herein control the flow path of plasma therethrough utilizing the tubular conduits 240. This minimizes recirculation of plasma which may result in surface collisions as well as a longer residence time, both of which may result in recombination.

While the foregoing is directed to implementations of the present disclosure, other and further implementations of the disclosure may be devised without departing from the basic scope thereof, and the scope thereof is determined by the claims that follow.

1. A diffuser, comprising:
a body having a first surface and a second surface opposing the first surface;
a plurality of dome structures formed in the first surface, each dome structure having an opening;
a central manifold formed in the second surface, the central manifold having a plurality of openings; and
a plurality of tubular conduits, each tubular conduit having two integral portions and coupled between one opening in the central manifold and a respective opening in one of the plurality of dome structures, at least a portion of the plurality of tubular conduits being positioned diagonally relative to a plane of the first surface.

2. The diffuser of claim 1, wherein each of the plurality of tubular conduits include a first portion and a second portion that is different than the first portion.

3. The diffuser of claim 2, wherein the first portion includes a diameter that is greater than a diameter of the second portion.

4. The diffuser of claim 2, wherein a length of a portion of the first portions is varied while a length of each of the second portions are the same.

5. The diffuser of claim 1, wherein each of the plurality of dome structures include a wall that is angled relative to the plane of the first surface.

6. The diffuser of claim 5, wherein a portion of the walls contact an adjacent wall of another dome structure.

7. The diffuser of claim 1, wherein each of the plurality of dome structures include a flare angle of about 120 degrees.

8. The diffuser of claim 1, wherein the plurality of tubular conduits comprises a central tubular conduit, and the central conduit is angled at about 180 degrees relative to the plane of the first surface.

9. The diffuser of claim 1, wherein the number of dome structures is equal to the number of tubular conduits.

10. A diffuser, comprising:
a body having a first surface and a second surface opposing the first surface;
a plurality of dome structures formed in the first surface, each dome structure having an opening;
a central manifold formed in the second surface, the central manifold having a plurality of openings; and
a plurality of tubular conduits each coupled between one opening in the central manifold and a respective opening in one of the plurality of dome structures, wherein each of the plurality of tubular conduits include a first portion and a second portion that is different than the first portion and at least a portion of the plurality of tubular conduits are positioned diagonally relative to a plane of the first surface, and wherein the number of dome structures is equal to the number of tubular conduits.

11. The diffuser of claim 10, wherein the first portion includes a diameter that is greater than a diameter of the second portion.

12. The diffuser of claim 10, wherein a length of a portion of the first portions is varied while a length of each of the second portions are the same.

13. The diffuser of claim 10, wherein each of the plurality of dome structures include a wall that is angled relative to the plane of the first surface.

14. A processing chamber, comprising:
a diffuser;
a first remote plasma source disposed over the diffuser;
a chamber wall, wherein the diffuser is disposed over the chamber wall;
a second remote plasma source coupled to the chamber wall;
a substrate support disposed below the diffuser; and
a plasma delivery ring disposed between the diffuser and the substrate support.

15. The processing chamber of claim 14, wherein the diffuser comprises:
a body having a first surface and a second surface opposing the first surface;
a plurality of dome structures formed in the first surface;
a central manifold formed in the second surface; and
a plurality of tubular conduits coupled between the central manifold and a respective one of the plurality of dome structures.

16. The processing chamber of claim 15, wherein at least a portion of the plurality of tubular conduits are positioned diagonally relative to a plane of the first surface.

17. The processing chamber of claim 15, wherein each of the plurality of tubular conduits include a first portion and a second portion that is different than the first portion.

18. The processing chamber of claim 17, wherein the first portion includes an inside diameter that is greater than an inside diameter of the second portion.

19. The processing chamber of claim 17, wherein the first portion includes a length that is greater than a length of the second portion.

20. The processing chamber of claim 15, wherein each of the plurality of dome structures include a wall that is angled relative to the plane of the first surface.
